(19) United States
(12) Patent Application Publication
(10) Pub. No.: US 2003/0161200 A1
(43) Pub. Date: Aug. 28, 2003

(54) Memory device and memory accommodating device

(76) Inventor: Nobuhiro Fujiwara, Kanagawa (JP)

Correspondence Address: FROMMER LAWRENCE & HAUG LLP, 745 FIFTH AVENUE, NEW YORK, NY, 10151, US

(21) Appl. No.: 10/373,439

(22) Filed: Feb. 25, 2003

(30) Foreign Application Priority Data
Feb. 26, 2002 (JP) P2002-050217

(51) Int. Cl. G11C 7/00

(52) U.S. Cl. 365/200

(57) ABSTRACT

A memory device including a card body including an antenna element and an integrated circuit element, the antenna element being used for performing data communication with a data reader without contacting the data reader, and the integrated circuit element being used for storing data exchanged between the integrated circuit element and the data reader through the antenna element. An electric-wave absorbing member is provided on a back surface of the card body so as to cover the antenna element. Even when a plurality of such memory devices are superimposed upon each other and accommodated in a card case, it is possible to reliably perform data communication with the data reader.

### BACKGROUND OF THE INVENTION

1. Field of the Invention

The present invention relates to a memory device which can exchange data with a data reader without contacting the data reader, and a device for accommodating the memory device.

2. Description of the Related Art

Hitherto, an integrated circuit (IC) card has been provided as a memory device which can perform data communication without contacting a data reader. The IC card is used as a prepaid card or a commuter pass which can pass through a ticket gate of a railway, or a prepaid card used for communication or for talking on a public telephone. Such types of IC cards each incorporate an antenna element and an integrated circuit element in the interior thereof. The antenna element receives an electric wave transmitted from a data reader, which is provided at a ticket gate or a public telephone, when these types of IC cards are brought close to the data reader. The integrated circuit element stores data exchanged between it and the data reader and controls writing and reading of the data. For example, prepaid amount data for the owner of the IC card is recorded in a memory circuit of the IC card.

When an IC card is brought close to a data reader that is provided at a ticket gate or a public telephone at the time of use, the antenna element receives amount-of-money reduction data transmitted from the data reader, an operation for reducing the amount of money is performed on the prepaid amount data stored in the memory circuit in accordance with the received amount-of-money reduction data, and billing completion data is transmitted to the data reader from the antenna element. When the data reader receives the billing completion data transmitted from the IC card, the owner of the IC card is permitted to pass the ticket gate, to talk on the public telephone, or to start communications.

In the case where the same type of IC cards are accommodated in one card case, when the IC cards are brought close to the data reader, data communication is sometimes not possible due to interference between the IC cards because they use electric waves of the same frequency band. Therefore, the user needs to take out the IC card to be used from the card case and then bring it close to the data reader, thereby causing trouble to the user.

Such IC cards are used in various applications. Therefore, the user often owns a plurality of IC cards of the same type and of different types. For example, a plurality of IC cards are often accommodated in one card case. In such a case, even if different types of IC cards are used, when IC cards using frequencies that are the same or almost the same are accommodated in one card case, the same problem as that mentioned above arises.

Related IC cards merely comprise one antenna element and one integrated circuit element, so that, when the user owns a larger number of cards, it is difficult to store them.

### SUMMARY OF THE INVENTION

Accordingly, in view of such problems described above, it is an object of the present invention to provide a memory device which can reliably perform data communication with a data reader even when a plurality of memory devices are superimposed upon each other and accommodated in a card case.

It is another object of the present invention to provide a memory device having a function corresponding to the functions of a plurality of memory devices.

It is still another object of the present invention to provide a memory device which can reliably perform data communication with a data reader even when a plurality of memory devices are superimposed upon each other and accommodated.

The present invention makes it possible to reliably perform data communication between a data reader and a memory device by preventing interference by an electric wave when the memory device is near the data reader by providing an electric-wave absorbing member at either the memory device or a memory accommodating device.

According to one aspect of the present invention, there is provided a memory device comprising a body including an antenna element and a memory element. The antenna element is used for performing data communication with a data reader without contacting the data reader, and the memory element is used for storing data exchanged between the memory element and the data reader through the antenna element. The body has an electric-wave absorbing member disposed on one of the surfaces of the body so as to cover the antenna element.

According to another aspect of the present invention, there is provided a memory accommodating device comprising a body for accommodating memory devices. Each memory device includes an antenna element and a memory element. The antenna element is used for performing data communication with a data reader without contacting the data reader, and the memory element is used for storing data exchanged between the memory element and the data reader through the antenna element. The body has accommodating sections disposed at respective sides of the body. The accommodating sections hold the respective memory devices so that electric-wave incident surfaces thereof upon which electric waves from the data reader are incident face the outside. The body has an electric-wave absorbing member disposed at a partition, which partitions the accommodating sections, so as to cover the antenna elements of the respective memory devices accommodated in the respective accommodating sections.

### BRIEF DESCRIPTION OF THE DRAWINGS

FIG. 1 shows an IC card to which the present invention is applied in perspective and from the front side thereof;

FIG. 2 shows the IC card in perspective and from the back side thereof;

FIG. 3 is a sectional view of the IC card;

FIG. 4 is an exploded sectional view of the IC card;

FIG. 5A illustrates an electric-wave reflecting member, and FIG. 5B illustrates an electric-wave absorbing member;

FIG. 6 is a perspective view illustrating a state in which the IC card is accommodated in an existing card case;

FIG. 7 illustrates a method of use of the IC card;

FIG. 8 is a sectional view illustrating an example in which the electric-wave absorbing member is disposed on side surfaces of a card body in addition to the back surface of the card body;

FIG. 9 is a sectional view illustrating an example in which the electric-wave absorbing body is provided on the entire back surface of the card body;

FIG. 10 is a sectional view illustrating an example in which the electric-wave absorbing member and a metallic plate which is the electric-wave reflecting member are superimposed upon each other;

FIG. 11 is a sectional view illustrating an example in which a sheet member forming the back surface of the card body is formed by the electric-wave absorbing member using two-color molding;

FIG. 12 is a sectional view illustrating an example in which the electric-wave absorbing member is interposed between two IC cards in order to form them into an integral structure;

FIG. 13 is a perspective view illustrating a card case having an electric-wave absorbing member provided thereat; and

FIG. 14 is a sectional view of the card case.

### DESCRIPTION OF THE PREFERRED EMBODIMENTS

Hereunder, an IC card that is used as a memory device of the present invention is described with reference to the drawings.

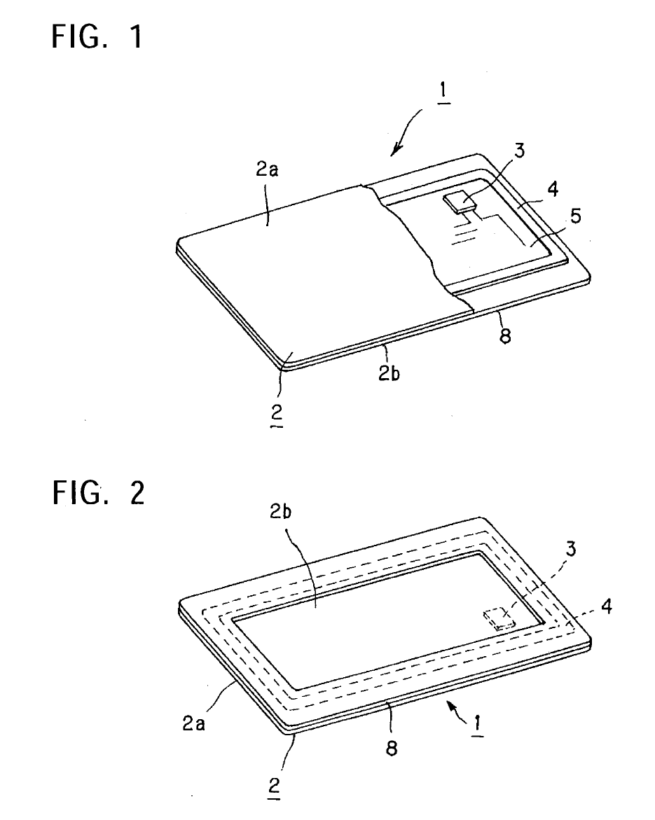

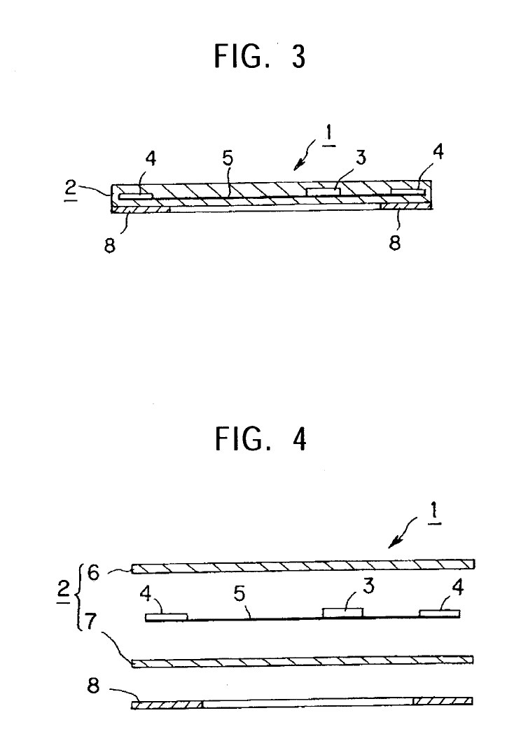

As shown in FIGS. 1 to 4, an IC card 1 to which the present invention is applied is used as a prepaid card or a commuter pass which can pass through a ticket gate of a railway. The IC card 1 comprises a substantially rectangular card body 2 that incorporates an integrated circuit element 3 and an antenna element 4. In the card body 2, a flexible or a rigid, substantially rectangular printed circuit board 5 having the integrated circuit element 3 and the antenna element 4 formed thereon is sandwiched by sheet members 6 and 7. The integrated circuit element 3 is, for example, a semiconductor element, and incorporates, for example, a memory circuit for storing data, a control circuit for controlling reading and writing of data stored in the memory circuit, and a drive circuit for driving various circuits by converting an electric wave received by the antenna element 4 into electrical power. In other words, by not using a battery in the IC card 1, the IC card 1 is made smaller and thinner. The antenna element 4, connected to the integrated circuit element 3, is provided with a substantially annular shape along the periphery of the substantially rectangular printed circuit board 5. The sheets 6 and 7, which sandwich the printed circuit board 5 having the integrated circuit element 3 and the antenna element 4 formed thereon, are formed of synthetic resin, such as PET (polyethylene terephthalate), and have sizes that are large enough to sufficiently cover the printed circuit board 5. With the printed circuit board 5 having the integrated circuit element 3 and the antenna element 5 formed thereon being interposed between the sheet members 6 and 7, these component parts are formed into an integral structure by, for example, thermal compression bonding.

One surface of the card body 2, formed by interposing the printed circuit board 5 between the sheet members 6 and 7 and subjecting them to thermal compression bonding, is a light-incident surface 2a upon which an electric wave from a data reader is incident and the other surface opposing the light-incident surface 2a is a back surface 2b.

An electric-wave absorbing member 8 is provided on the back surface 2b of the card body 2. The electric-wave absorbing member 8 is used for preventing an electric wave from the data reader from impinging upon the back surface 2b and for preventing transmission of the electric wave to the data reader from the back surface 2b, is provided with a substantially annular shape along the back surface 2b of the substantially rectangular card body 2 so as to cover the antenna element 4 incorporated in the card body 2, and is formed wider than the antenna element 4 so that it can sufficiently absorb the electric wave at the back surface 2b side. The electric-wave absorbing member 8 is mounted to the back surface 2b of the card body 2 using, for example, an adhesive.

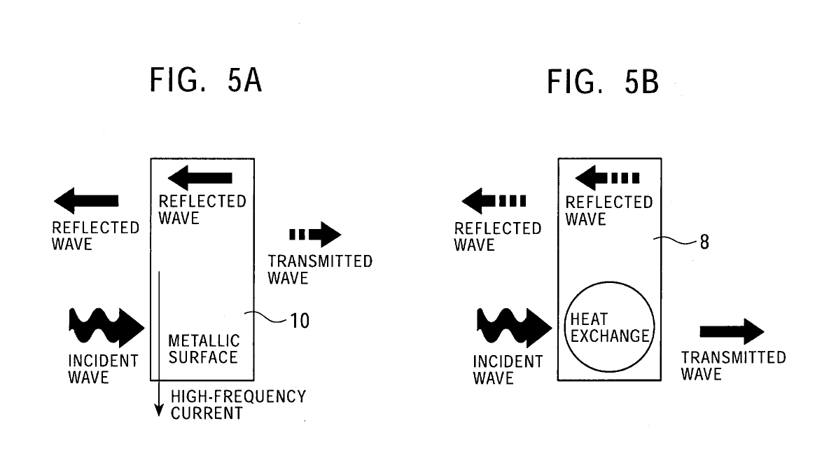

Here, the electric-wave absorbing member 8 is described in more detail with reference to FIG. 5. The electric-wave absorbing member 8 is a sheet-like member formed by hardening a soft magnetic material, such as ferrite, with a binder. The sheet-like member has a high surface electrical resistance of from 10⁴ to 10⁷ Ω and a thickness of from 0.05 mm to 0.1 mm. As shown in FIG. 5A, in the case where, instead of the electric-wave absorbing member 8, a ferromagnetic material, that is, a conductive metal 10 is used at the back surface 2b of the card body 2, when an electric wave is incident upon the metal 10, the amount of transmitted wave can be made small, but a high-frequency current flows at the surface of the metal 10 and reflected waves having phases that are different from the phase of the incident wave are generated. The high-frequency current flowing at the surface of the metal 10 produces reradiation noise when connection to ground (GND) is improper. Therefore, if there is another IC card near the IC card that is used, such as an IC card superimposed upon the IC card 1 that is used, the IC card 1 and the other IC card interfere with each other, so that it may not be possible to perform data communication.

On the other hand, as shown in FIG. 5B, the electric-wave absorbing member 8 comprising a soft magnetic material as a main component can absorb electromagnetic waves, that is, electric waves by converting the energy of the incident wave into heat energy. In the IC card 1, by providing the electric-wave absorbing member 8 on the back surface 2b of the card body 2, electric waves are prevented from entering the card body 2 from the back surface 2b, so that data communication with the data reader can be performed at the light-incident surface 2a.

In the embodiment, the operating frequency of the IC card 1 when it performs data communication with the data reader is, for example, 13.56 MHz, and the electric-wave absorbing member 8 is required to be one which can at least absorb an electrical wave having this operating frequency. Here, the electric-wave absorbing member 8 that is used can absorb an electric wave having a frequency range of, for example, from 10 to 1000 MHz. Obviously, the frequency band that the electric-wave absorbing member 8 absorbs is determined in relation to the operating frequency of the IC card 1 that is used, so that the electric-wave absorbing member 8 may be capable of absorbing other frequency bands.

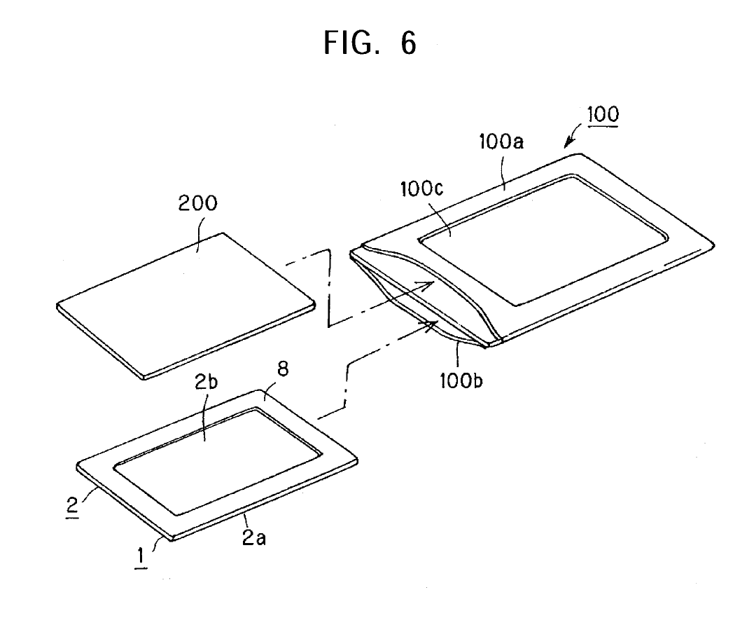

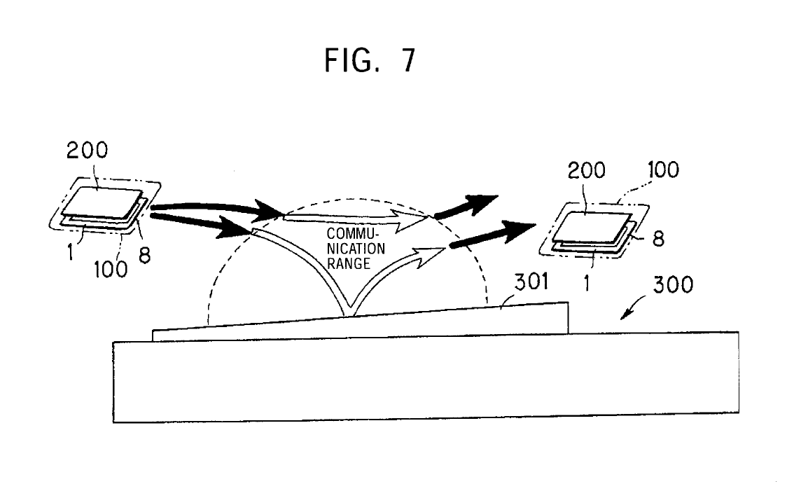

The method of use of the above-described IC card 1 will be described with reference to FIGS. 6 and 7. Ordinarily, the IC card 1 is accommodated in a card case 100 by a user. As shown in FIG. 6, the card case 100 comprises a first accommodating section 100b and a second accommodating section 100c at respective sides of a body 101a formed of, for example, synthetic resin or leather. The first and second accommodating sections 100b and 100c can accommodate, for example, magnetic-recording cards, such as the IC card 1 and a commuter pass. For example, the first accommodating section 100b accommodates the IC card 1 having the electric-wave absorbing member 8 to which the present invention is applied provided on the back surface 2b of the card body 2 and the second accommodating section 100c accommodates an IC card 200 not having an electric-wave absorbing member 8. The IC card 1 is accommodated in the first accommodating section 100b with the light-incident surface 2a of the card body 2 facing outward. In other words, the IC card 1 and the IC card 200 are accommodated in the card case 100 so as to be superimposed upon each other. The IC card 200 may be accommodated in the second accommodating section 100c with either surface facing outward. Accordingly, the IC card 1 that is accommodated in the card case 100 is used as shown in FIG. 7.

Here, a data reader 300 has a transmitting-and-receiving section 301 provided thereat for performing data communication with the IC card 1 and the IC card 200. The transmitting-and-receiving section 301 incorporates an antenna element for performing data communication with the IC card 1 and the IC card 200, and transmits an electric wave which is such as to make the distance that allows communication with the IC card 1 and the IC card 200 to be, for example, 10 cm. In other words, in performing data communication with the data reader 300, the IC card 1 or the IC card 200 do not necessarily need to be brought into contact with the transmitting-and-receiving section 301. Therefore, as long as the IC card 1 or the IC card 200 is brought within a predetermined range from the transmitting-and-receiving section 301, data communication can be performed even if the IC card 1 or the IC card 200 is not in contact with the transmitting-and-receiving section 301.

The IC card 1 which is accommodated in the first accommodating section 101b of the card case 100 and to which the present invention is applied is brought close to the transmitting-and-receiving section 301 so that the light-incident surface 2a of the card body 2 faces the transmitting-and-receiving section 301. When the IC card 1 is brought close to the transmitting-and-receiving section 301 in this way, the antenna element 4 of the IC card 1 receives an electric wave transmitted from the transmitting-and-receiving section 301 of the data reader 300. The electric wave is converted into electric power in order to drive the integrated circuit element 3. The IC card 1 receives amount-of-money reduction data transmitted from the transmitting-and-receiving section 301 of the data reader 300 and performs an operation for reducing the amount of money on the prepaid amount data stored in the memory circuit of the integrated circuit element 3 in accordance with the received amount-of-money reduction data, and transmits billing completion data to the transmitting-and-receiving section 301 of the data reader 300 from the antenna element 4. When the data reader 300 receives the billing completion data transmitted from the IC card 1, the owner of the IC card 1 is permitted to pass the ticket gate.

At this time, the electric-wave absorbing member 8 is provided on the back surface 2b of the card body 2 of the IC card 1. Therefore, by absorption of the electric wave transmitted from the transmitting-and-receiving section 301 by the electric-wave absorbing member 8 of the IC card 1, an antenna element of the IC card 200 that is accommodated in the second accommodating section 101c of the card case 100 does not receive the electric wave transmitted from the transmitting-and-receiving section 301 of the data reader 300. In this way, by providing the electric-wave absorbing member 8 on the back surface 2b of the card body 2, even if the IC card 1 is superimposed upon the IC card 200 by being accommodated in the card case 100, interference by the electric wave does not occur, so that the IC card 1 can reliably perform data communication with the transmitting-and-receiving section 301 of the data reader 300.

Next, the case where the IC card 200 is used when it is superimposed upon the IC card 1 to which the present invention is applied as a result of being accommodated in the card case 100 is described. With the surface of the IC card 200 facing the outside of the second accommodating section 101c being the light-incident surface, the IC card 200 is made to face and is brought close to the transmitting-and-receiving section 301 of the data reader 300. Then, as described above, the IC card 200 performs data communication with the transmitting-and-receiving section 301 of the data reader 300. At this time, the IC card 1 to which the present invention is applied is accommodated in the first accommodating section 101b of the card case 100. Since an electric wave is absorbed by the electric-wave absorbing member 8, which is provided on the back surface 2b of the card body 2, the IC card 1 does not detect the electric wave from the transmitting-and-receiving section 301 of the data reader 300. Therefore, even if the IC card 200 is superimposed upon the IC card 1 as a result of being accommodated in the card case 100, the IC card 200 can reliably perform data communication with the data reader 300.

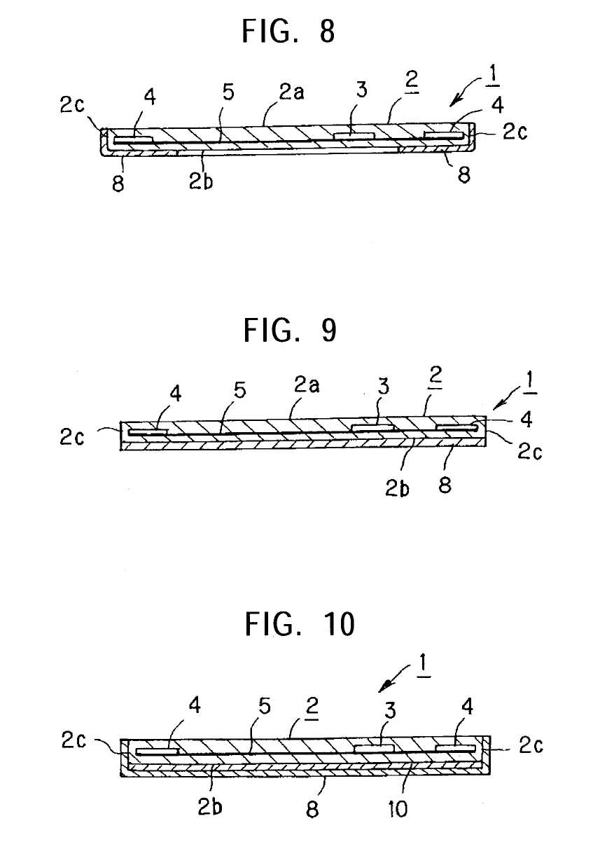

The electric-wave absorbing member 8 used in the IC card 1 to which the present invention is applied may also be provided on the back surface 2b of the card body 2 in the following way. The IC card 1 shown in FIG. 8 is formed so that its electric-wave absorbing member 8 that is provided on the back surface 2b of the card body 2 also covers side surfaces 2c of the card body 2. In other words, the electric-wave absorbing member 8 is formed so that a portion thereof is formed with an annular shape on the back surface 2b of the card body 2 along the outer periphery of the back surface 2b so as to cover the antenna element 4 that is formed with a substantially annular shape along the outer periphery of the card body 2 inside the card body 2, and so that other portions thereof formed integrally with the portion of the electric-wave absorbing member 8 on the back surface 2b cover the side surfaces 2c of the card body 2. By this, the IC card 1 shown in FIG. 8 can more reliably absorb an electric wave than the other IC card 1 having the electric-wave absorbing member 8 provided only along the outer periphery of the back surface 2b of the card body 2.

In the IC card 1 shown in FIG. 9, the electric-wave absorbing member 8 is provided along the entire back surface 2b of the card body 2. Since the electric-wave absorbing member 8 is provided along the entire back surface 2b, the IC card 1 shown in FIG. 9 can more reliably absorb an electric wave than the IC card 1 having its electric-wave absorbing member 8 provided with an annular shape on the back surface 2b of the card body 2 along the outer periphery of the back surface 2b. By a combination of the examples shown in FIGS. 8 and 9, the electric-wave absorbing member 8 of the IC card 1 may also be provided so that a portion thereof is provided along the entire back surface 2b of the card body 2 and other portions thereof are formed on the side surfaces 2c of the card body 2 and integrally with the portion of the electric-wave absorbing member 8 formed on the entire back surface 2b. By this, the IC card 1 can absorb more electric waves than the IC cards 1 shown in FIGS. 8 and 9.

The ferromagnetic, that is, conductive metal 10, which has been described with reference to FIG. 5A, excels in its capability of reducing transmitted waves compared to the electric-wave absorbing member 8 comprising a soft magnetic material as a main component and used in the IC card 1. Therefore, as shown in FIG. 10, the metallic plate 10 and the electric-wave absorbing member 8 may be used in combination in the IC card 1. In other words, the metallic plate 10, which reflects an electric wave, may be affixed to the entire back surface 2b of the card body 2 with, for example, an adhesive, and the electric-wave absorbing member 8 may be provided on the metallic plate 10 along the entire back surface 2b. The metallic plate 10 is connected to ground (GND).

In the IC card 1 shown in FIG. 10, electric waves incident thereupon from the back-surface-2b side of the card body 2 are first absorbed by the electric-wave absorbing member 8, with any electric waves transmitted through the electric-wave absorbing member 8 being reflected by the metallic plate 10. The waves reflected by the metallic plate 10 can be absorbed by the electric-wave absorbing member 8. Therefore, compared to the IC cards 1 described above, the IC card 1 shown in FIG. 10 can prevent electric waves incident thereupon from the back-surface-2b side of the card body 2 from being received by the antenna element 4 incorporated inside the card body 2. Obviously, the electric-wave absorbing member 8 and the metallic plate 10 do not need to be provided on the entire back surface 2b of the card body 2. They may be provided with annular shapes along the outer periphery of the back surface 2b of the card body 2, or they may be provided on the side surfaces 2c as well as along the outer periphery of the back surface 2b.

Other examples of methods for forming two layers by the electric-wave absorbing member 8 and the metallic plate 10 are as follows. In one example, first, the electric-wave absorbing member 8 is provided on the entire back surface 2b of the card body 2 or is provided with an annular shape along the outer periphery of the back surface 2b of the card body 2, and the metallic plate 10 is provided upon the electric-wave absorbing member 8 along the entire back surface 2b of the card body 2 or with an annular shape along the outer periphery of the back surface 2b of the card body 2. In another example, the metallic plate 10 is sandwiched by the electric-wave absorbing member 8, and these are provided on the back surface 2b of the card body 2.

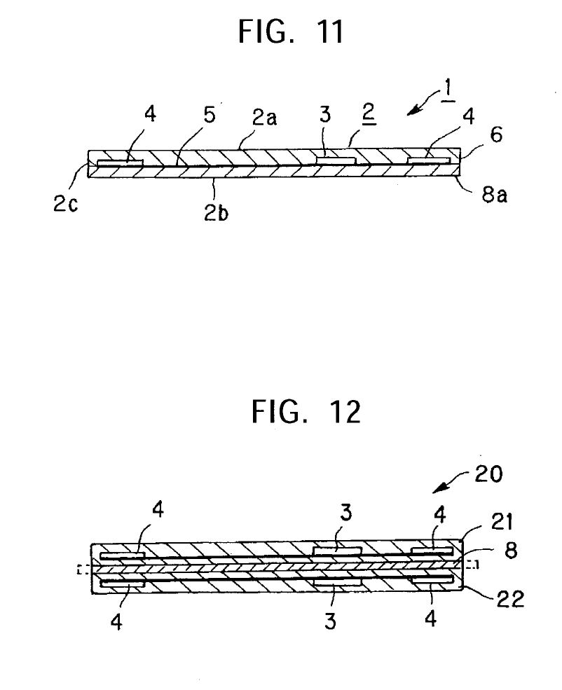

As shown in FIG. 4, in the card body 2 of the IC card 1, the printed circuit board 5 having the integrated circuit element 3 and the antenna element 4 formed thereon is interposed between the sheet members 6 and 7, and these component parts are integrally formed by, for example, thermal compression bonding. As shown in FIG. 11, in the IC card 1, the synthetic resin sheet member 7, which forms the bottom surface of the card body 2, may be used as a sheet member 8a that is formed by the electric-wave absorbing member 8. By this, in the IC card 1 shown in FIG. 11, it is not necessary to additionally provide the electric-wave absorbing member 8 on the back surface 2b of the card body 2. Therefore, it is possible for the IC card 1 shown in FIG. 11 to have substantially the same thickness as the existing IC card 200 while having the aforementioned electric-wave absorbing function.

As described with reference to FIG. 6, even if the IC card 1 is superimposed upon the existing IC card 200 in the card case 100 as a result of accommodating the above-described IC card 1 in the card case 100, interference therebetween by an electric wave is prevented from occurring, so that the IC card 1 can perform data communication with the data reader 300. However, in the present invention, as shown in FIG. 12, the IC card 1 and the existing IC card 200 in the card case 100 may be integrally formed.

More specifically, as shown in FIG. 12, an IC card 20 comprises a first card body 21 and a second card body 22. Since the first card body 21 and the second card body 22 have structures that are similar to the structure of the card body 2, they will not be described in detail below. Printed circuit boards 5 each having an integrated circuit element 3 and an antenna element 4 provided thereon are sandwiched by respective synthetic resin sheet members and these component parts are integrally formed by, for example, thermal compression bonding. Then, an electric-wave absorbing member 8 having the same size as the first card body 21 and the second card body 22 is interposed between the first card body 21 and the second card body 22. The first card body 21 and the electric-wave absorbing member 8 and the second card body 22 and the electric-wave absorbing member 8 are integrally formed with, for example, an adhesive.

This means that one IC card 20 has the function of two related IC cards 200. Therefore, the user can reduce the number of IC cards that he owns, and can easily, for example, handle the cards. Although, in the IC card 20, two card bodies incorporating antenna elements are superimposed upon each other, since the electric-absorbing member 8 is interposed between the first card body 21 and the second card body 22, it is possible to prevent the first card body 21 and the second card body 22 from interfering with each other when performing data communication with the data reader 300, so that data communication with the data reader 300 can be reliably carried out.

As shown by the dotted lines in FIG. 12, the electric-wave absorbing member 8 used in the IC card 20 may be slightly larger, for example, approximately 0.1 mm larger, than the first and second card members 21 and 22, so that interference occurs less frequently between the first and second card bodies 21 and 22.

In addition to an IC card, the present invention may be applied to, for example, a memory device that is provided at a recording medium cartridge, such as a tape cartridge or a disk cartridge. There are recording medium cartridges which are used to record, for example, images, and those which are used to record, for example, processing data that is processed by a computer. These recording medium cartridges, for example, have the same external shapes, but different recording formats, so that recording and/or reproducing operations cannot be performed with the same recording and/or reproducing device. In addition, since such recording medium cartridges record a large amount of data, the user may sometimes forget what is stored in the recording medium cartridges. Accordingly, a semiconductor memory chip is provided at one side surface of the cartridge body of such recording medium cartridges, and data is recorded on the semiconductor memory chip. When this type of recording medium cartridge is loaded into a recording and/or reproducing device, the recording and/or reproducing device performs radio communication with the semiconductor memory device in order to read out data stored in the semiconductor memory device and display it on a display section, and updated data is stored in the semiconductor memory device. There is a changer recording and/or reproducing device which accommodates a plurality of recording medium cartridges of this type, and records data onto and/or reproduces data from a selected one of the recording medium cartridges. When the charger recording and/or reproducing device performs data communication with a semiconductor memory of one of the accommodated plurality of recording medium cartridges, interference by electric waves occurs between the semiconductor memory of the recording medium cartridge and a semiconductor memory of another nearby recording medium cartridge as with the IC cards described above, so that it may not be possible to perform data communication between the recording and/or reproducing device and the semiconductor memory device of the recording medium cartridge. In the present invention, this problem may be overcome by providing an electric-wave absorbing member on one of the surfaces of a semiconductor memory device used in a recording medium cartridge.

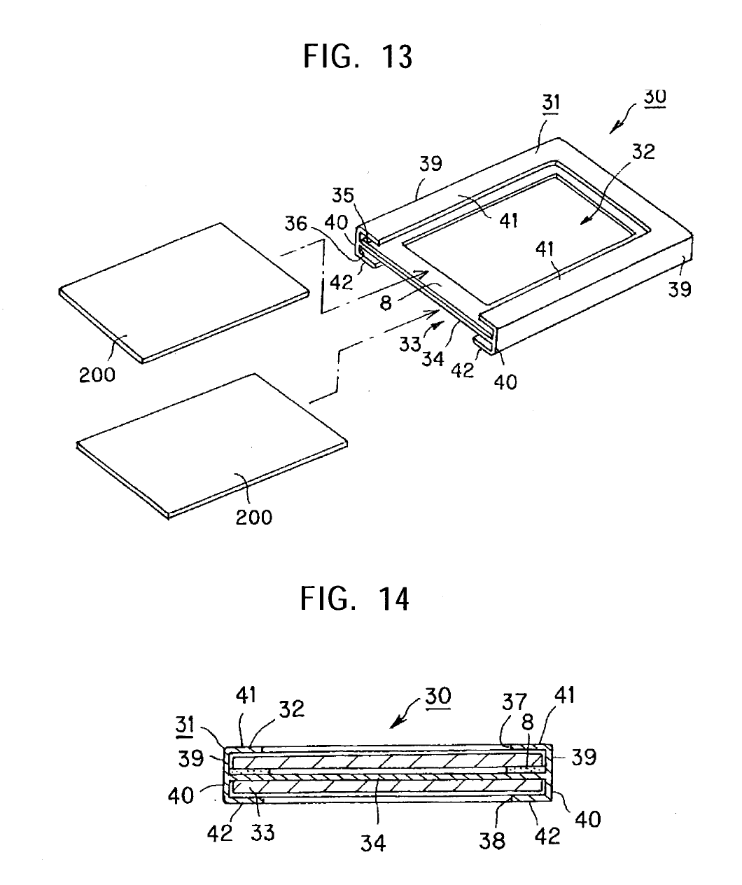

Next, a description of a card case to which the present invention is applied will be given with reference to FIGS. 13 and 14. A card case 30 to which the present invention is applied can accommodate a plurality of the above-described existing IC cards 200. For example, the card case 30 accommodates two IC cards 200 that are superimposed upon each other. The card case 30 has a body 31 that is molded out of, for example, synthetic resin. The body 31 comprises a first accommodating section 32 disposed at one side thereof for accommodating an existing IC card 200, and a second accommodating section 33 disposed at the other side thereof for accommodating another existing IC card 200. The first accommodating section 32 and the second accommodating section 33 are partitioned by a partition plate 34, and are provided continuously with a first insertion opening 35 and a second insertion opening 36, respectively, which are provided in one side surface of the body 31 and which are used for inserting and taking out the respective existing IC cards 200. The first accommodating section 32 is formed by a pair of guide walls 39 and a pair of holders 41, and the second accommodating section 33 is formed by a pair of guide walls 40 and a pair of holders 42. The pair of guide walls 39 and the pair of guide walls 40 are formed in an upstanding manner from the side edges of the partition plate 34 that are parallel to the direction of insertion of the IC cards 200. The pair of holders 41 and the pair of holders 42 hold the respective IC cards 200 and are formed so as to extend integrally with and inwardly of the respective pair of guide walls 39 and pair of guide walls 40, and parallel to the partition plate 34. A first opening 37 is disposed between the pair of holders 41 and 41 forming the first accommodating section 32. The first opening 37 is formed continuously with the first insertion opening 35 so as to allow one of the surfaces of the accommodated IC card 200 to face the outside. A second opening 38 is disposed between the pair of holders 42 and 42 forming the second accommodating section 33. The second opening 38 is formed continuously with the second insertion opening 36 so as to allow one of the surfaces of the accommodated IC card 200 to face the outside.

An electric-wave absorbing member 8 is provided on the surface at the first-accommodating-section-32 side of the partition plate 34. The electric-wave absorbing member 8 is provided with a substantially annular shape along the outer periphery of the partition plate 34 and at a location that allows it to cover the antenna elements 4 incorporated in the existing IC cards 200 accommodated in the respective first and second accommodating sections 32 and 33. Obviously, the electric-wave absorbing member 8 may be provided entirely on one of the surfaces of the partition plate 34, or entirely on or along the periphery of the other surface of the partition plate 34.

In the above-described card case 30, two existing IC cards 200 are accommodated in the first and second accommodating sections 32 and 33, respectively. The IC cards 200 are guided and inserted along the respective guide walls 39 and guide walls 40 from the respective first and second insertion openings 35 and 36, and are accommodated and held by the respective first and second accommodating sections 32 and 33 by the respective holders 41 and holders 42 and engagers (not shown). Unlike the above-described IC cards 1, the IC cards 200 accommodated in the card case 200 do not have electric-wave absorbing members 8 provided on the back surfaces thereof. Therefore, by the antenna elements incorporated in the respective card bodies, the IC cards 200 can receive electric waves transmitted from the transmitting-and-receiving section 301 of the data reader 300 from both the front and back surfaces of the IC cards 200. Consequently, the IC cards 200 can be accommodated in the respective first and second accommodating sections 32 and 33 without having to face the front and back sides in particular directions. In addition, the IC cards 200 accommodated in the respective first and second accommodating sections 32 and 33 are such that the surfaces thereof facing the outside from the respective first and second openings 37 and 38 are electric-wave incident surfaces for performing data communication with the data reader 300.

Accordingly, when one of the IC cards 200 accommodated in the respective first and second accommodating sections 32 and 33 is used, the IC card 200 that is used is brought close to the transmitting-and-receiving section 301 of the data reader 300 so as to face it. When the IC card 200 is brought close to the transmitting-and-receiving section 301 in this way, an antenna element of the IC card 200 receives an electric wave transmitted from the transmitting-and-receiving section 301 of the data reader 300. The electric wave is converted into electric power in order to drive an integrated circuit element of the IC card 200. The IC card 200 receives amount-of-money reduction data transmitted from the transmitting-and-receiving section 301 of the data reader 300 and performs an operation for reducing the amount of money on the prepaid amount data stored in a memory circuit of the integrated circuit element in accordance with the received amount-of-money reduction data, and transmits billing completion data to the transmitting-and-receiving section 301 of the data reader 300 from the antenna element 4. When the data reader 300 receives the billing completion data transmitted from the IC card 200, the owner of the IC card 200 is permitted to pass a ticket gate.

Here, the electric-wave absorbing member 8 is provided at the partition plate 4 of the card case 30. Therefore, by absorption of the electric wave transmitted from the transmitting-and-receiving section 301 of the data reader 300 by the electric-wave absorbing member 8, the antenna element of the IC card 200 that is not used accommodated in the card case 100 does not receive the electric wave transmitted from the transmitting-and-receiving section 301 of the data reader 300. In this way, in the card case 30, by providing the electric-wave absorbing member 8 at the partition plate 34, even if the existing IC cards 200 are superimposed upon each other, interference by the electric wave is prevented from occurring, so that the IC card 200 that is used can reliably perform data communication with the transmitting-and-receiving section 301 of the data reader 300. It is also possible to accommodate the IC card 1 in the card case 30.

The card case to which the present invention is applied is not limited to this card case, so that the partition plate 34 itself may be formed by the electric-wave absorbing member 8 or the entire body 31 may be formed by the electric-wave absorbing member 8. When the entire body 31 is formed by the electric-wave absorbing member 8, the holders 41 and the holders 42 are formed small, and the area of the card body that incorporates the antenna elements that are incorporated in the IC cards 200 is such as not to be completely covered by the holders 41 and the holders 42, so that the antenna elements are in an electrical wave receivable state. Alternatively, when the entire body 31 is formed by the electric-wave absorbing member 8, the IC cards 200 may be held by the respective first and second accommodating sections 32 and 33 by other means other without providing the holders 41 and holders 42.

Although, in the above-described forms of the present invention, the case where an antenna element is provided along the periphery of a card body of an IC card is described, the location of the antenna element in the IC card used in the present invention is not limited thereto, so that the location where the antenna element is disposed is relatively determined in relation to where the antenna element is disposed in the IC card.

According to the present invention, by interposing an electric-wave absorbing member between memory devices, even if they are superimposed upon each other, it is possible to prevent failure of data communication with a data reader caused by interference by an electric wave.

What is claimed is:

1. A memory device comprising:
a body including an antenna element and a memory element, the antenna element being used for performing data communication with a data reader without contacting the data reader, and the memory element being used for storing data exchanged between the memory element and the data reader through the antenna element,
wherein the body has an electric-wave absorbing member disposed on one of the surfaces of the body so as to cover the antenna element.

2. A memory device according to claim 1, wherein the one surface of the body is defined as a surface opposing a surface for performing the data communication with the data reader, the one surface having the electric-wave absorbing member disposed thereon.

3. A memory device according to claim 2, wherein the electric-wave absorbing member is further disposed on side surfaces of the body.

4. A memory device according to claim 2, wherein the antenna element is disposed along an outer periphery of the body, and wherein the electric-wave absorbing member is disposed along an outer periphery of the one surface of the body.

5. A memory device according to claim 2, wherein the electric-wave absorbing member is disposed entirely on the one surface.

6. A memory device according to claim 1, wherein the electric-wave absorbing member is lined with a metallic plate.

7. A memory device according to claim 1 having another memory device integrally superimposed upon the one surface side thereof where the electric-wave absorbing member is disposed, the other memory device being capable of performing data communication with the data reader without contacting the data reader.

8. A memory device according to claim 1, wherein the body has a structure in which the memory element and the antenna element are sandwiched by sheet members, with the sheet member which provides the one surface of the body being formed by the electric-wave absorbing member.

9. A memory device according to claim 1, wherein the body is a card-type body.

10. A memory device according to claim 1, wherein the electric-wave absorbing member comprises soft magnetic material.

11. A memory device according to claim 8, wherein the electric-wave absorbing member comprises ferrite powder as a main component.

12. A memory accommodating device comprising:
a body for accommodating memory devices, each memory device including an antenna element and a memory element, the antenna element being used for performing data communication with a data reader without contacting the data reader, and the memory element being used for storing data exchanged between the memory element and the data reader through the antenna element,
wherein the body has accommodating sections disposed at respective sides thereof, the accommodating sections holding the respective memory devices so that electric-wave incident surfaces thereof upon which electric waves from the data reader are incident face the outside, and
wherein the body has an electric-wave absorbing member disposed at a partition, which partitions the accommodating sections, so as to cover the antenna elements of the respective memory devices accommodated in the respective accommodating sections.

13. A memory accommodating device according to claim 12, wherein the body is formed by the electric-wave absorbing member.

14. A memory accommodating device according to claim 12, wherein the antenna elements of the memory devices are disposed along outer peripheries of the memory devices, and wherein the electric-wave absorbing member is disposed along an outer periphery of the partition.

15. A memory accommodating device according to claim 12, wherein the electric-wave absorbing member is disposed on an entire surface of the partition.

16. A memory accommodating device according to claim 12, wherein the memory device is a card-type memory device.

17. A memory accommodating device according to claim 12, wherein the electric-wave absorbing member comprises soft magnetic material.

18. A memory accommodating device according to claim 17, wherein the electric-wave absorbing member comprises ferrite powder as a main component.
